(19) United States
(12) Patent Application Publication
(10) Pub. No.: US 2019/0097331 A1
(43) Pub. Date: Mar. 28, 2019

(54) SURFACE MOUNT CONNECTOR AND METHOD OF FORMING A PRINTED CIRCUIT BOARD

(71) Applicant: GE Aviation Systems Limited, Gloucestershire (GB)

(72) Inventors: Michael James Smith, Chadlington (GB); Peter James Handy, Cheltenham (GB); Alexander James Rainbow, Swindon (GB)

(21) Appl. No.: 16/112,823

(22) Filed: Aug. 27, 2018

(30) Foreign Application Priority Data
Sep. 25, 2017 (GB) 1715474.1

(51) Int. Cl. H01R 12/57; H01R 12/58; H01R 43/20; H01R 43/02; H05K 1/18; H05K 3/30

(52) U.S. Cl. CPC H01R 12/57; H01R 12/585; H01R 43/205; H05K 2201/10189; H05K 1/184; H05K 3/306; H01R 43/0256

(57) ABSTRACT

A surface mount connector and method of forming a printed circuit board includes providing a printed circuit board having a first aperture extending there through, and receiving a surface mount connector at the printed circuit board, the surface mount connector having a connector body and a flange, the connector body received by and aligned with the first aperture.

### BACKGROUND OF THE INVENTION

Printed circuit boards (PCBs) can support and interconnect set of electrical components such as capacitors, resistors, processors, and the like. In addition to interconnecting the electrical components, PCBs can include electrical or conductive connectors for connecting electrical components not supported or included on the PCB. Examples of electrical components not supported or included on the PCB can include power supplies or power connections, actuators, or other systems communicatively coupled with the PCB by way of pins, contacts, wires, louvres, or the like.

### BRIEF DESCRIPTION OF THE INVENTION

In one aspect, the present disclosure relates to a surface mount connector for a printed circuit board includes a connector body having opposing first and second ends, and a flange mounted to the first end of the connector body having a distal flange end extending perpendicular to the connector body and beyond the connector body. The connector body is sized to be received in a through hole of a printed circuit board and the flange is electrically connectable to the printed circuit board.

In another aspect, the present disclosure relates to a printed circuit board, including a substrate having a first aperture and a surface-layer trace, and a surface mount connector fixed to the substrate and conductively connected with the trace, the surface mount connector having a connector body having opposing first and second ends, the first end having a flange defining a distal flange end extending perpendicular to the connector body and beyond the connector body, and the second end received by the first aperture.

In yet another aspect, the present disclosure relates to a method of forming a printed circuit board, including providing a printed circuit board having a first aperture extending there through and an arrangement of a set of second apertures spaced about the first aperture, receiving a surface mount connector at the printed circuit board, the surface mount connector having a connector body received by and aligned with the first aperture and a set of pins extending downwardly toward the printed circuit board, the set of pins supported by a perpendicular flange at an end of the connector body and received by and aligned with the set of second apertures, and applying a force urging the surface mount connector toward the printed circuit board to press-fit the set of pins in a frictional relationship with the set of second apertures.

### BRIEF DESCRIPTION OF THE DRAWINGS

In the drawings:

FIG. 1 illustrates an isometric view of a surface mount connector and a printed circuit board (PCB) in accordance with various aspects described herein.

FIG. 2 illustrates a cut away view of the surface mount connector and PCB of FIG. 1, in accordance with various aspects described herein.

FIG. 3 illustrates a cut away view of another surface mount connector and a PCB, in accordance with various aspects described herein.

FIG. 4 illustrates a cut away view of yet another surface mount connector and PCB, in accordance with various aspects described herein.

FIG. 5 is an example a flow chart demonstrating a method of forming a printed circuit board in accordance with various aspects described herein.

### DESCRIPTION OF EMBODIMENTS OF THE INVENTION

Aspects of the disclosure can be implemented in any environment, apparatus, or method wherein an electrical connector or connection is disposed or otherwise connected with a planar surface, such as at a printed circuit board (PCB).

While “a set of” various elements will be described, it will be understood that “a set” can include any number of the respective elements, including only one element. Connection references (e.g., attached, coupled, connected, and joined) are to be construed broadly and can include intermediate members between a collection of elements and relative movement between elements unless otherwise indicated. As such, connection references do not necessarily infer that two elements are directly connected and in fixed relation to each other. In non-limiting examples, connections or disconnections can be selectively configured to provide, enable, disable, or the like, an electrical connection between respective elements.

As used herein, the terms “axial” or “axially” refer to a dimension along a longitudinal axis of an engine or along a longitudinal axis of a component disposed within the engine. As used herein, the terms “radial” or “radially” refer to a dimension extending between a center longitudinal axis of a component, an outer circumference, or a circular or annular component disposed within another component or referencing point. All directional references (e.g., radial, axial, upper, lower, upward, downward, left, right, lateral, front, back, top, bottom, above, below, vertical, horizontal, clockwise, counterclockwise) are only used for identification purposes to aid the reader's understanding of the disclosure, and do not create limitations, particularly as to the position, orientation, or use thereof.

The exemplary drawings are for purposes of illustration only and the dimensions, positions, order and relative sizes reflected in the drawings attached hereto can vary.

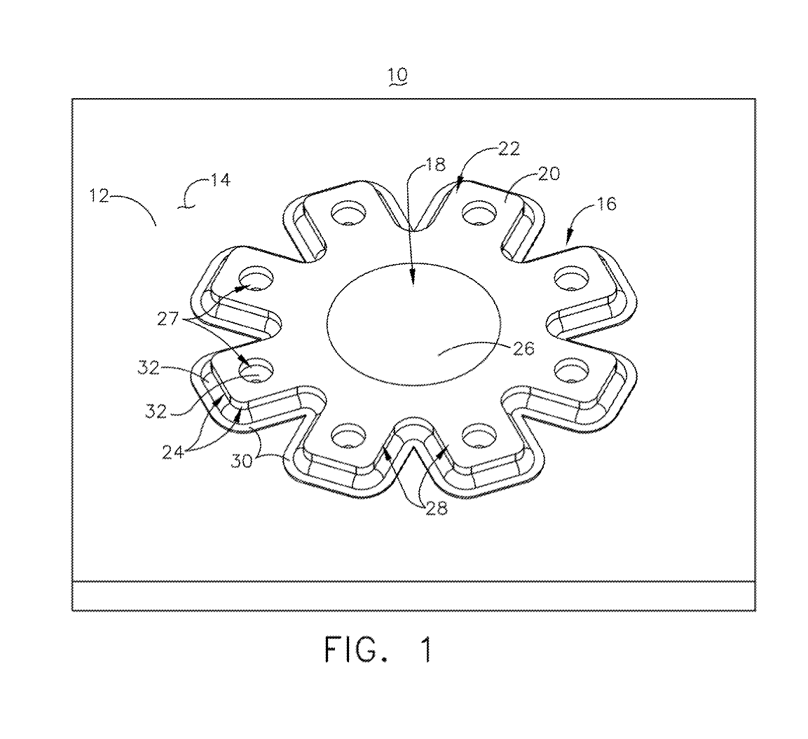

FIG. 1 illustrates an assembly 10 for a planar surface such as a printed circuit board 12 having an electrical or conductive connection with a surface mount connector 16. As shown, the PCB 12 can define a top or upper surface 14 defining at least one electrically conductive pathway associated with the PCB 12 or the upper surface, such as an electrical trace 30, shown as a conductive pad. Non-limiting aspects of the PCB 12 or trace 30 can be included wherein the trace 30 is electrically connected with another electrical element or component (not shown).

The surface mount connector 16 can include at least one flange 20 disposed at or above the upper surface 14 of the PCB 12 and a body connector 26 extending downwardly through the PCB 12 in a direction perpendicular or normal to the at least one of the flange 20, the PCB 12, or the upper surface 14. In one non-limiting example, the flange 20 and the body connector 26 can be a unitary component formed by an electrically conductive material. The body connector 26 can be better seen in the following figures.

Non-limiting aspects of the disclosure can include an opening 18 in at least one of the flange 20 and the body connector 26. As shown, the opening 18 can be circular, however alternative geometric openings, contours, shapes (including polygonal, etc.) can be included. In one non-limiting example the opening 18 can define an opening that extends through the flange 20 and body connector 26. In another non-limiting example, the opening 18 can include aspects, connectors, contacts (such as sprung contacts or louvres, for example) associated with at least one of the flange 20 or the body connector 26 for receiving or connecting with another component. In another non-limiting example, the opening 18, contacts, or the like can be adapted to receive or connect with a power supplying component, such as a bus bar conductor.

The flange 20 can include a distal flange end 22, wherein “distal” is in reference to a distance or spacing away from the flange 20 center, the body connector 26, or another referential component of the surface mount connector 16. In this sense, “distal” can include a radial spacing away from the referential component. In aspects wherein the opening 18 of the surface mount connector 16 includes an axial center, “distal” can be in reference to a distance spacing away from the axial center.

The distal flange end 22 can include at least one circumferential edge 24 tracking the outer surface of the distal flange end 22. As used herein, a “circumferential” edge 24 does not necessarily denote a circular or ovate arrangement, configuration, or the like. Rather, a “circumferential” edge 24 denotes that the edge 24 encompasses a circumferential span about the distal flange end 22. In one non-limiting aspect, the circumferential edge 24 can extend in one continuous surface at least partially perpendicular to the upper surface 14 of the PCB 12. In another non-limiting aspect, the circumferential edge 24 can be solderable, for example, to the underlying trace 30. In the illustrated example, the circumferential edge 24 is electrically connected and at least partially fixed relative to the trace 30 by solder 32. Any suitable solder 32 can be utilized in aspects of the disclosure. Non-limiting aspects can be included wherein at least one of the solder 32 or flange 20 is configured, spaced, or the like, relative to the trace 30, such that solder 32 can flow under at least a portion of the flange to ensure electrical contact between the surface mount connector 16 and the trace 30.

In non-limiting aspects of the disclosure, the flange 20 or distal flange ends 22 can be shaped, contoured, patterned, or the like to increase the total circumferential edge 24 length about the flange 20, for example, compared with a standard geometric flange 20 configuration (circle, square, polygonal, etc.). For instance, as shown, the flange 20 or distal flange ends 22 can include a set of arms 28 shaped or formed in the flange 20. In this sense, the set of arms 28 increase the total circumferential edge 24 length by defining portions of the circumferential edge 24 that extend at least partially radially inward toward the flange 20 center, the opening 18, or the body connector 26, as well as at least partially radially outward toward the distal flange end 22, or the set of distal flange ends 22 (e.g. wherein each respective arm 28 includes a respective distal flange end 22). In another non-limiting aspect of the disclosure, the flange 20 can further include a set of perforations 27 shaped, contoured, patterned, or the like, to further define an edge solderable to the trace 30. At least one of the set of arms 28 or the set of perforations 27 can be, for example, circumferentially spaced about the flange 20. Collectively, the circumferential edge 24, the set of perforations 27, or a combination thereof, can define a solderable connection that can fix the flange 20 or the surface mount connector 16 relative to the PCB 12, the upper surface 14, the trace 30, or a combination thereof.

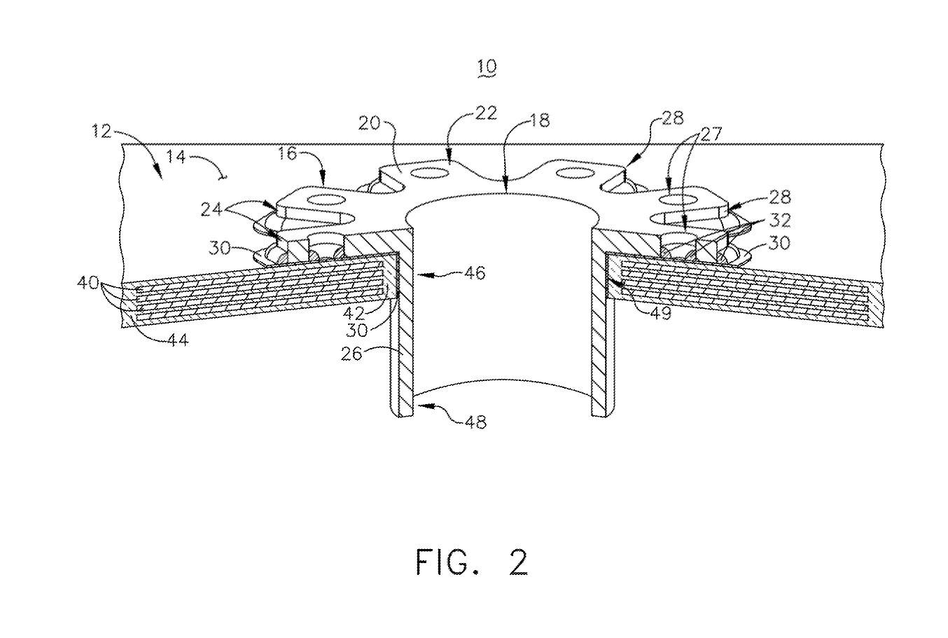

FIG. 2 illustrates a partial cutaway view of the assembly 10. As shown, the body connector 26 can include a first end 46 mounted or connected with the flange 20 and an opposing second end 48 spaced from the first end 46. At least a portion of the second end 48 of the body connector 26 can be received there through by a first aperture 49 of the PCB 12 during assembly. Non-limiting examples of the first aperture 49 and the body connector 26 can be adapted, formed, tailored, or the like to align, or include corresponding contours such that the second end 48 is received by the first aperture 49. In one non-limiting example, the adapting, forming, tailoring, or the like, of the second end 48, the body connector 26, the first aperture 49, or a combination thereof, can provide spacing or tolerances such that the receiving of the second end 48 or the body connector 26 by the first aperture 49 does not create a friction relationship or “press-fit” relationship between the respective components. Stated another way, the surface mount connector 16 is fixed relative to the PCB 12 by way of the solder 32 or solder connections, not by way of press-fitting the body connector 26 within the first aperture 49. The first end 46 can further be received by the first aperture 49 of the PCB 12 when the surface mount connector 16 is fully assembled (e.g. when the surface mount connector 16 is fixed relative to the PCB 12, as shown in FIG. 2).

Non-limiting aspects of the connector body 26 can include a generally cylindrical form (as shown), however any polygonal or non-polygonal forms can be included, and correspond with the first aperture 49, as described. In another non-limiting example, aspects of at least one of the connector body 26, the first aperture 49, or a combination thereof can include an orientation-type configuration, such as keying, forming, shaping, or contouring, such that the connector body 26 can only be received by the first aperture 49 in a subset of predetermined or predefined orientations. In another non-limiting example, the subset of predetermined or predefined orientations can, for example, align the surface mount connector 16 or flange 20 with the trace 30.

Also as shown, at least one of the flange 20, the distal flange end 22, the set of arms 28, or a combination thereof, can extend perpendicular to the connector body 26 and beyond the connector body 26. As shown, at least one of the flange 20, the distal flange end 22, the set of arms 28, or a combination thereof, extend away from the opening 18, an axial center of the connector body 26, or the outer boundary of the connector body 26, in a direction substantially parallel to the PCB 12 or upper surface 14. In this sense, the delineation of where the flange 20 “begins” and the connector body 26 “ends” can include, but is not limited to, a portion of the surface mount connector 16 extending above the upper surface 14, a portion of the surface mount connector 16 extending beyond the outermost boundary of the body connector 26 extending in the direction of the PCB 12 or upper surface 14, or a combination thereof.

FIG. 2 further illustrates a better view of the electrical trace 30 configuration. As shown, non-limiting configurations of the trace 30 can extend along the upper surface 14 of the PCB 12, and can further extend along the inner surface of the first aperture 49. At least a portion of the trace 30 disposition can ensure a reliable electrically conductive contact between the surface mount connector 16 and the PCB 12.

The PCB 12 can include any number of configurations or compositions. For example, as shown, the PCB 12 can include an insulated metal substrate having a non-conductive substrate 44 portion and at least one conductive metal layer 40 encompassed or enveloped within the non-conductive substrate 44. In one non-limiting configuration of the insulated metal substrate PCB 12, a portion of the PCB 12 proximate to the first aperture 49 can be adapted to include an insulating portion 42 of the non-conductive substrate 44 to prevent electrical contact between the surface mount connector 16 or the body connector 26 and the at least one metal layer 40. In one example, the insulated metal substrate PCB 12 can be adapted or configured to provide thermal management capabilities to the PCB 12. In one instance, the at least one metal layer 40 is thermally conductive, and can be utilized for heat-spreading about the PCB 12, that is, conducting heat from one portion of the PCB 12 to another portion, to manage or reduce localized heat build-up.

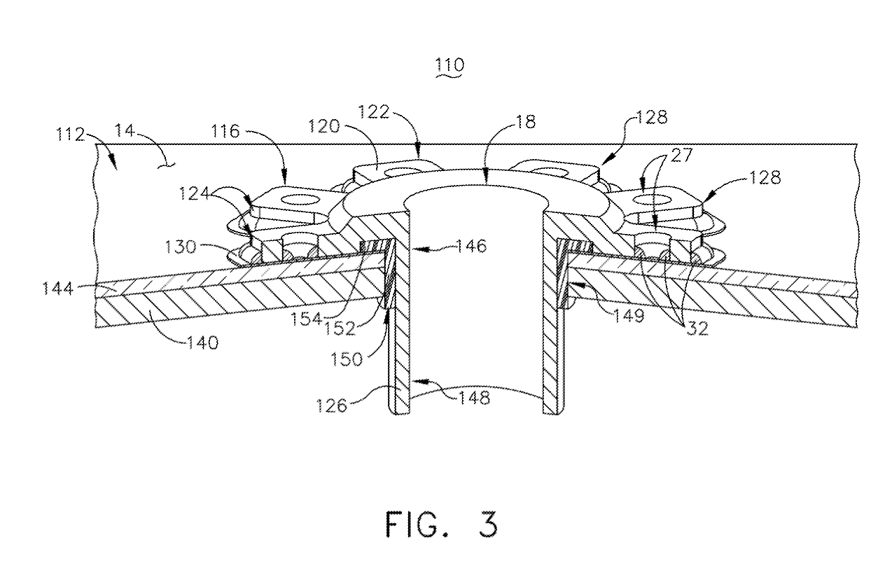

FIG. 3 illustrates another assembly 110 according to another aspect of the present disclosure. The assembly 110 is similar to the assembly 10; therefore, like parts will be identified with like numerals increased by 100, with it being understood that the description of the like parts of the assembly 10 applies to the assembly 110, unless otherwise noted. One difference is that the PCB 112 can include a direct bonded metal substrate having a non-conductive substrate 144 portion defining the upper surface 14 and a continuous conductive metal layer 140 defining the lower portion of the PCB 112. As shown, the metal layer 140 is not contained or otherwise insulated by the non-conductive substrate 144 expect for the upper surface 14 of the assembly 110. Thus, non-limiting aspects of the assembly 110, the surface mount connector 116, the PCB 112, or a component thereof, can include a non-conductive insulating collar 150 disposed about the first aperture 149 to electrically insulate the surface mount connector 116 or the connector body 126 from the metal layer 140. As shown, the insulating collar 150 can include a first portion 152 extending downwardly toward the second end 148 of the connector body, passing the substrate 144 and the metal layer 140 and a second portion 154 extending parallel with upper surface 14 of the PCB 112. Non-limiting examples of the insulating collar 150 can ensure clearances and creepage separation between respective components.

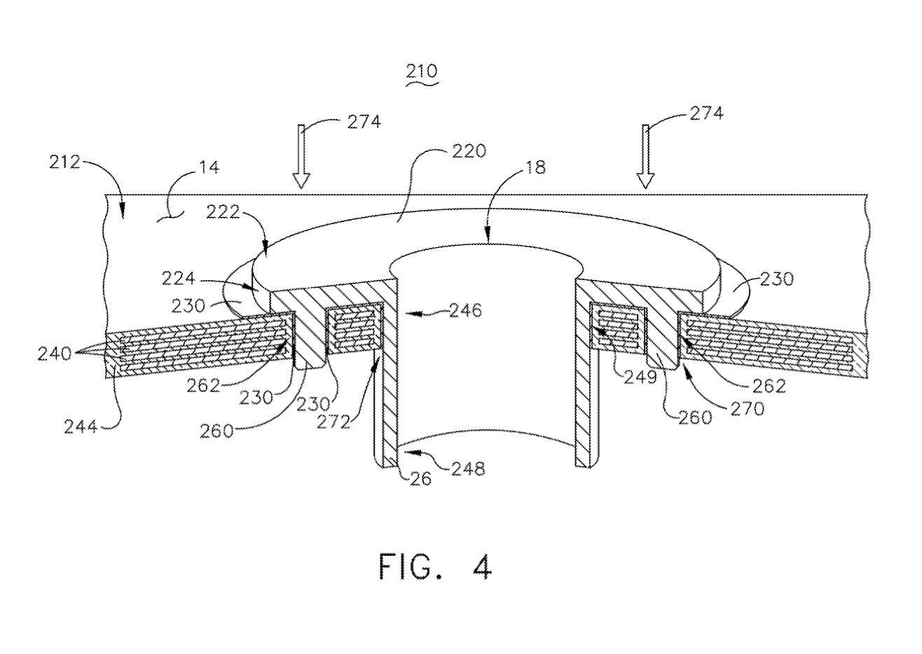

FIG. 4 illustrates another assembly 210 according to another aspect of the present disclosure. The assembly 210 is similar to the assembly 10; therefore, like parts will be identified with like numerals increased by 200, with it being understood that the description of the like parts of the assembly 10 applies to the assembly 210, unless otherwise noted. One difference is that the flange 220 of the surface mount connector 216 can include a set of pins 260 extending away from the underside of the flange 220 toward the second end 248 of the connector body 26. While only two pins 260 are illustrated in the cut away view of FIG. 4, non-limiting aspects of the disclosure can include a set of pins 260 circumferentially or radially arranged, disposed, patterned, the like, or a combination thereof, about the flange 220.

The PCB 212, similarly, can include a set of second apertures 262 aligned with or matching the set of pins 260 such that the set of pins 260 can be received by the set of second apertures 262 during assembly. As shown, the set of second apertures 262 can be lined with the trace 230, as previously described. In another non-limiting example, aspects of at least one of the set of pins 260, the set of second apertures, or a combination thereof can include an orientation-type configuration, such as keying, forming, shaping, disposition, or contouring, such that the surface mount connector 216 can only be received by the PCB 212 in a subset of predetermined or predefined orientations. In another non-limiting example, the subset of subset of predetermined or predefined orientations can, for example, align the surface mount connector 216 or flange 20 with the trace 230.

The sizing or dimensioning of at least one of the set of pins 260 or the set of second apertures 262 can further be tailored, configured, adapted or otherwise determined such that the receiving of the set of pins 260 in the respective set of second apertures 262 can result in a frictional-fit or press-fit relationship between the surface mount connector 216 and the PCB 212. For instance, when assembled with a downward-directed force (toward the receiving of the connector body 26 or set of pins 260 within the respective first or set of second apertures 249, 262, illustrated schematically as arrows 274), the interfacing of the set of pins 260 with the set of second apertures 262 fictionally engage each other such that the surface mount connector 216 is fixed relative to the PCB 212. The resulting friction relationship ensures a press-fit connection 270 between the respective pins 260 and second aperture 262. In one non-limiting example, the adapting, forming, tailoring, or the like, of the second end 248, the body connector 26, the first aperture 249, or a combination thereof, can provide spacing or tolerances such that the receiving of the second end 248 or the body connector 26 by the first aperture 249 does not create a friction relationship or “press-fit” relationship 272 between the respective components. Stated another way, the surface mount connector 216 is fixed relative to the PCB 12 by way of the press-fit connection between the respective pins 260 and second apertures 262, not by way of press-fitting the body connector 26 within the first aperture 249.

While not illustrated, non-limiting aspects of the flange 220 configuration of FIG. 4 can be included with the direct bonded metal substrate PCB 112 of FIG. 3, with modifications. For example, the direct bonded metal substrate PCB 112 of FIG. 3 can include a set of second apertures 262 and a set of insulating collars 150 for a corresponding set of pins 260.

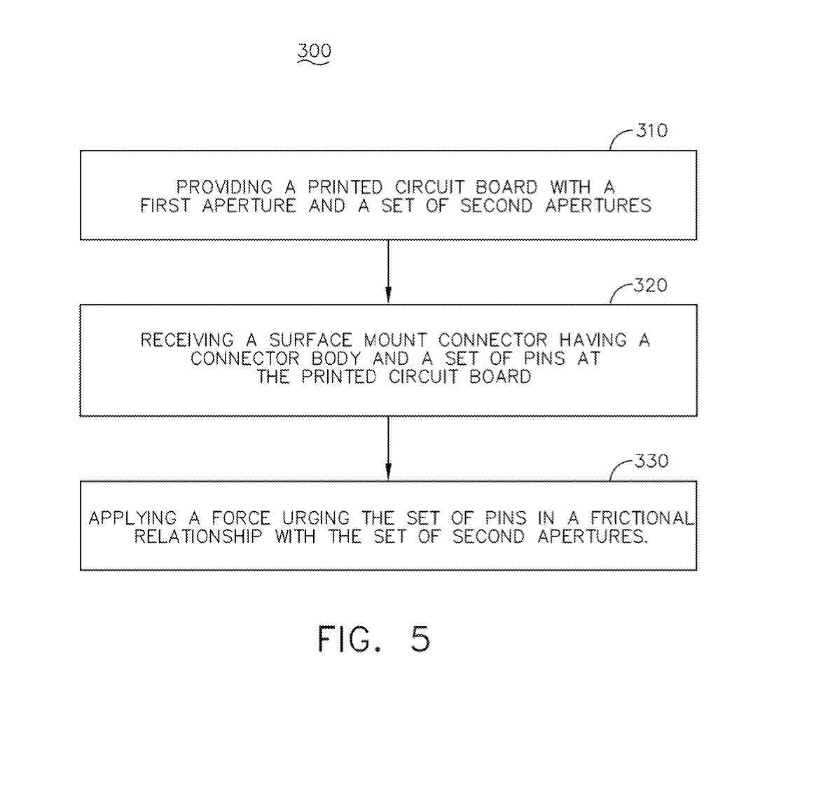

FIG. 5 illustrates a flow chart demonstrating a method 300 of forming a printed circuit board 212. The method 300 begins by providing a printed circuit board 212 having a first aperture 249 extending there through and an arrangement of a set of second apertures 262 spaced about the first aperture 249, at 310. Next the method 300 continues to receiving a surface mount connector 216 at the printed circuit board 212, at 320. The surface mount connector 216 can include the connector body 26 received by and aligned with the first aperture 249 and a set of pins 260 extending downwardly toward the printed circuit board 212, the set of pins 260 supported by a perpendicular flange 220 at an end of the connector body 26 and received by and aligned with the set of second apertures 262. The method 300 can then include applying a force 274 urging the surface mount connector 216 toward the printed circuit board 212 to press-fit the set of pins 260 in a frictional relationship 270 with the set of second apertures 262, at 330.

The sequence depicted is for illustrative purposes only and is not meant to limit the method 300 in any way as it is understood that the portions of the method can proceed in a different logical order, additional or intervening portions can be included, or described portions of the method can be divided into multiple portions, or described portions of the method can be omitted without detracting from the described method.

Many other possible aspects and configurations in addition to that shown in the above figures are contemplated by the present disclosure. Additionally, the design and placement of the various components such as valves, pumps, or conduits can be rearranged such that a number of different in-line configurations could be realized.

The aspects disclosed herein provide a surface mount connector and method of forming a printed circuit board. Commercially available pass-through power connectors typically install by press-fit into bus bars and not directly to PCBs. This in turn requires a carrier bus bar to be soldered, bolted, press fit or mated by additional connector to the PCB. Existing methodologies further introduce additional electrical interfaces within a given current path, introducing electrical resistances that generate heat in response to power transmission, and reduces reliability. Any interface that requires a press-fit into the PCB further impacts or limits the real estate or available surface area on all PCB layers within a traditional board construction and requires an additional (non-solder based) process to be added to the PCB assembly.

In one non-limiting advantage, aspects of the disclosure introduces a direct surface mounting that is soldered to the PCB that reduces electrical interfaces within a system and enables use with alternative board constructions where press-fit arrangements would not have been appropriate. For instance, increasing power density in electronics or electrical components supported by a PCB can result in non-traditional board constructions to improve thermal performance. In some instances, conventional through-hole connectors are prohibited due to requirements for electrical isolation of the metallic substrates. Thus another non-limiting advantage of aspects of the disclosure enable the surface mounting of the connector (via solder).

An advantage of the soldered surface mount described herein is that only the top surface of the PCB needs be utilized to make electrical contact. Another advantage of the soldered surface mount described herein is that fixing of the surface mount connector to the PCB can be accomplished with a press-fit connector, which can introduce additional electrical interfaces, an additional process during assembly, impacting PCB real estate and tracking on internal layers of the PCB, and potentially risk PCB delamination due to physical disruption of press-fitting methods.

An advantage of the press-fitting surface mount aspects is that it can enable higher current transfer, compared with the soldered assembly utilizing similar PCB footprint. Another advantage of the above-described aspects of the press-fit assembly includes the reduction in electrical interfaces, as described, ability for direct electrical connections to sub-surface PCB traces or vias, and no resulting increases in temperature or dwell times during a solder process

Fewer electrical interfaces can result in less voltage drop or power losses through the connector, increasing the overall efficiency of the electrical system. Additionally, fewer assembly steps can result in less costly manufacturing or assembly.

To the extent not already described, the different features and structures of the various aspects can be used in combination with each other as desired. That one feature cannot be illustrated in all of the aspects is not meant to be construed that it cannot be, but is done for brevity of description. Thus, the various features of the different aspects can be mixed and matched as desired to form new aspects, whether or not the new aspects are expressly described. Combinations or permutations of features described herein are covered by this disclosure.

This written description uses examples to disclose aspects of the disclosure, including the best mode, and also to enable any person skilled in the art to practice aspects of the disclosure, including making and using any devices or systems and performing any incorporated methods. The patentable scope of the disclosure is defined by the claims, and can include other examples that occur to those skilled in the art. Such other examples are intended to be within the scope of the claims if they have structural elements that do not differ from the literal language of the claims, or if they include equivalent structural elements with insubstantial differences from the literal languages of the claims.

What is claimed is:

1. A surface mount connector for a printed circuit board, comprising:
a connector body having opposing first and second ends; and
a flange mounted to the first end of the connector body having a distal flange end extending perpendicular to the connector body and beyond the connector body;
wherein the connector body is sized to be received in a through hole of a printed circuit board and the flange is electrically connectable to the printed circuit board.

2. The surface mount connector of claim 1 wherein the distal flange end includes a solderable circumferential edge and the distal flange end is shaped to increase the circumferential edge length about the flange.

3. The surface mount connector of claim 2 wherein the flange includes a set of arms extending radially away from the connector body and wherein the set of arms define a set of distal flange ends.

4. The surface mount connector of claim 1 wherein the flange includes a set of perforations circumferentially spaced about the flange.

5. The surface mount connector of claim 4 wherein the set of perforations define a respective set of solderable perforation edges.

6. The surface mount connector of claim 1 wherein the connector body is at least one of cylindrical or polygonal.

7. The surface mount connector of claim 1 wherein the flange includes a set of pins supported by the flange and extending away from the flange toward the second end of the connector body.

8. The surface mount connector of claim 7 wherein the set of pins are circumferentially arranged about the flange.

9. The surface mount connector of claim 7 wherein the set of pins are adapted to be press-fit into corresponding apertures of a printed circuit board to fix the surface mount connector to the printed circuit board.

10. A printed circuit board, comprising:
a substrate having a first aperture and a surface-layer trace; and
a surface mount connector fixed to the substrate and conductively connected with the trace, the surface mount connector having a connector body having opposing first and second ends, the first end having a flange defining a distal flange end extending perpendicular to the connector body and beyond the connector body, and the second end received by the first aperture.

11. The printed circuit board of claim 10 wherein the distal flange end includes a circumferential edge and the distal flange end is shaped to increase the circumferential edge length about the flange.

12. The printed circuit board of claim 11 wherein the flange includes a set of arms extending radially away from the connector body and wherein the set of arms define a set of distal flange ends.

13. The printed circuit board of claim 11 wherein the circumferential edge is soldered to the trace.

14. The printed circuit board of claim 10 wherein the flange includes a set of perforations circumferentially spaced about the connector body and define a respective set of perforation edges, and wherein the set of perforation edges are soldered to the trace.

15. The printed circuit board of claim 10 wherein the substrate includes a direct bonded metal substrate.

16. The printed circuit board of claim 15 further comprising an insulating collar adapted to electrically insulate the connector body from the direct bonded metal substrate.

17. The printed circuit board of claim 10 wherein the substrate includes an insulated metal substrate.

18. The printed circuit board of claim 10 wherein the flange includes a set of pins supported by the flange and extending away from the flange toward the second end of the connector body.

19. The printed circuit board of claim 18 wherein the substrate includes a second set of apertures aligned with the set of pins and adapted such that the receiving of the set of pins within the respective set of apertures results in a friction-fit relationship between the substrate and the surface mount connector.

20. A method of forming a printed circuit board, comprising:
providing a printed circuit board having a first aperture extending there through and an arrangement of a set of second apertures spaced about the first aperture;
receiving a surface mount connector at the printed circuit board, the surface mount connector having a connector body received by and aligned with the first aperture and a set of pins extending downwardly toward the printed circuit board, the set of pins supported by a perpendicular flange at an end of the connector body and received by and aligned with the set of second apertures; and
applying a force urging the surface mount connector toward the printed circuit board to press-fit the set of pins in a frictional relationship with the set of second apertures.
